(19) United States
(12) Patent Application Publication
(10) Pub. No.: US 2006/0278957 A1
(43) Pub. Date: Dec. 14, 2006

(54) FABRICATION OF SEMICONDUCTOR INTEGRATED CIRCUIT CHIPS

(76) Inventors: Zong-Huei Lin, Tai-Chung City (TW); Hung-Min Liu, Hsin-Chu City (TW); Jui-Meng Jao, Miao- Li Hsien (TW); Wen-Tung Chang, Hsin-Chu City (TW); Kuo-Ming Chen, Hsin-Chu Hsien (TW); Kai-Kuang Ho, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/160,106

(22) Filed: Jun. 9, 2005

(51) Int. Cl. H01L 23/544

(52) U.S. Cl. 257/620

(57) ABSTRACT

A semiconductor wafer includes a plurality of active circuit die areas, each of which being bordered by a dicing line region through which the plurality of active circuit die areas are separated from each other, wherein each of the plurality of active circuit die areas has substantially four corners. An overcoat is deposited to cover both the active circuit die areas and the dicing line region. A first trench is formed by etching through the overcoat and disposed merely around the four corners of each active circuit die area. A reinforcing second trench is etched into the overcoat and is disposed in proximity to the first trench. A die seal ring is disposed in between the active circuit chip area and the first trench.

### BACKGROUND OF INVENTION

1. Field of the Invention

The present invention relates generally to semiconductor integrated circuit devices and, more particularly, to the fabrication of semiconductor integrated circuit chips provided with a means of stopping propagation of interface de-lamination between dielectric layers originated from the wafer dicing process.

2. Description of the Prior Art

Semiconductor manufacturers have been shrinking transistor size in integrated circuits (IC) to improve chip performance. This has resulted in increased speed and device density. For sub-micron technology, the RC delay becomes the dominant factor. To facilitate further improvements, semiconductor IC manufacturers have been forced to resort to new materials utilized to reduce the RC delay by either lowering the interconnect wire resistance, or by reducing the capacitance of the inter-layer dielectric (ILD). A significant improvement was achieved by replacing the aluminum (Al) interconnects with copper, which has ˜30% lower resistivity than that of Al. Further advances are facilitated by the change of the low-k dielectric materials.

However, one shortcoming associated with the use of low-k dielectrics is that almost all low-k dielectric materials possess relatively lower mechanical strength than that of conventional silicon oxide dielectrics such as FSG or USG. The use of low-k dielectrics poses this industry another problem that the adhesion ability, either at the interface between two adjacent low-k dielectric layers or at the interface between a low-k dielectric layer and a dissimilar dielectric layer, is somewhat inadequate to meet the requirements in the subsequent wafer treatment processes such as wafer dicing, which is typically performed to mechanically cut a semiconductor wafer into a number of individual IC chips.

It has been found that the so-called “interface de-lamination” phenomenon occurs between low-k dielectric layers during or after the wafer dicing process is performed, causing performance degradation of the IC chips. In light of the above, a need exists in this industry to provide a solution to the undesired propagation of the interface de-lamination between low-k dielectric layers originated from the wafer dicing process.

### SUMMARY OF INVENTION

It is therefore an object of the present invention to provide an effective reinforcing structure, which is disposed deliberately around four vulnerable die corners in order to stop the propagation of interface de-lamination between low-k dielectric layers originated from the wafer dicing process.

In accordance with one preferred embodiment of this invention, a semiconductor wafer is provided. The semiconductor wafer includes a plurality of active circuit die areas, each of which being bordered by a dicing line region through which the plurality of active circuit die areas are separated from each other, wherein each of the plurality of active circuit die areas has substantially four corners. An overcoat is deposited to cover both the active circuit die areas and the dicing line region. A first trench is formed by etching through the overcoat and disposed merely around the four corners of each active circuit die area. A reinforcing second trench is etched into the overcoat and is disposed in proximity to the first trench. A die seal ring is disposed in between the active circuit chip area and the first trench.

From one aspect of this invention, a semiconductor wafer includes a plurality of active circuit die areas, each of which being bordered by a dicing line region through which the plurality of active circuit die areas are separated from each other by mechanical wafer dicing, wherein each of the plurality of active circuit die areas has substantially four corners. An overcoat covers both the active circuit die areas and the dicing line region. An inter-layer dielectric layer is disposed underneath the overcoat. A first trench is formed within the dicing line region, wherein the first trench is formed by etching through the overcoat into the inter-layer dielectric layer and is disposed merely around the four corners of each active circuit die area. A reinforcing second trench is etched into the overcoat and into the inter-layer dielectric layer, wherein the second trench is disposed in proximity to the first trench for preventing interface de-lamination of the inter-layer dielectric layer at the four corners during or after the mechanical wafer dicing. A die seal ring is disposed in between the active circuit chip area and the first trench.

According to another preferred embodiment of the present invention, the semiconductor wafer further includes a silicon substrate, and wherein at least one of the first and second trenches is formed by etching through the overcoat and the inter-layer dielectric layer, whereby reaching to the silicon substrate.

According to still another preferred embodiment of the present invention, the first trench and the reinforcing second trench are both triangular trenches, and wherein the reinforcing second trench encompasses the first trench.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is an enlarged, schematic plan view of the intersection of two dicing lines between the corners of four circuit chips of a semiconductor wafer in accordance with the first preferred embodiment of this invention;

FIG. 2 is a schematic cross section through the wafer (taken along line I-I) showing a dicing line, reinforcing structure and part of two adjacent circuit chips according to this invention;

FIG. 3 is a schematic plan view of a portion of a semiconductor wafer in accordance with the second preferred embodiment of this invention; and

FIG. 4 is a schematic plan view of a portion of a semiconductor wafer in accordance with the third preferred embodiment of this invention.

### DETAILED DESCRIPTION

The present invention pertains to the fabrication of semiconductor chips with a means of stopping propagation of interface de-lamination between low-k dielectric layers originated from the wafer dicing process. As stated supra, interface de-lamination phenomenon occurs between low-k dielectric layers during or after the wafer dicing. It has been observed that such interface de-lamination phenomenon is particularly severe at the corners of a single die or chip, and the interface de-lamination even penetrates into the active circuit die area protected by a die seal ring or metallic arrester wall, even in combination with a single crack-stopping trench slit along the perimeter of each die. It is believed that the severe interface de-lamination at the four corners of a single die results from mechanical stress created by the cutting blade during the wafer dicing process. During wafer dicing, either in the form of grinding-cutting or scribing, the aforesaid mechanical stress concentrates on the four corners of an active circuit die area, causing short-term or long-term reliability problems. In short, the protection on the wafer at the weak corners of a single die has been overlooked in the prior arts and published treatises to this day.

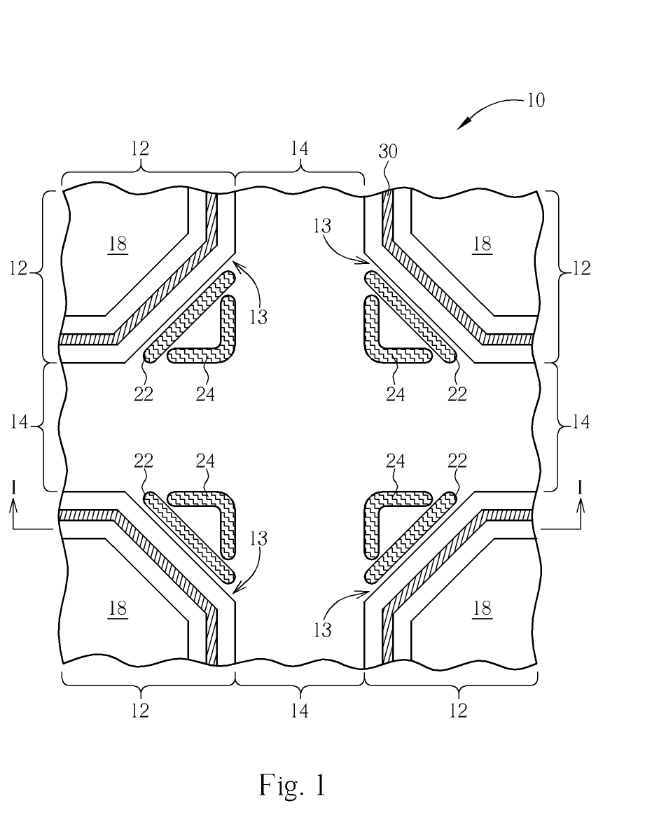

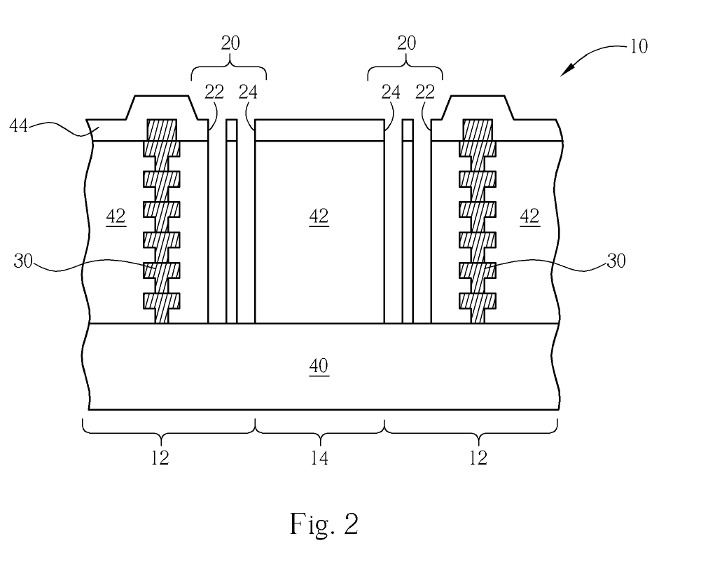

Please refer to FIG. 1 and FIG. 2. FIG. 1 is an enlarged, schematic plan view of the intersection of two dicing lines between the corners of four circuit chips of a semiconductor wafer 10 in accordance with one preferred embodiment of this invention. FIG. 2 is a schematic cross section through the wafer (taken along line I-I) showing a dicing line and part of two adjacent circuit chips. The semiconductor wafer 10 comprises a number of circuit chips 12, and for simplicity, only four of them are shown in FIG. 1. Each of the circuit chips 12 has substantially four corners 13. According to one preferred embodiment of this invention, the four corners 13 of each circuit chip 12 are not right-angled corners. The illustrated four circuit chips 12 are separated by the intersecting dicing lines 14, which intersect at substantially right angles. Within each circuit chip 12, an active integrated circuit 18 is fabricated, which may comprise components such as, for example, transistors, diffusions, memory arrays and interconnections.

The active integrated circuit 18 is surrounded by a typical seal ring structure 30, which is well known as a die seal ring. Such seal ring structure consists of a plurality of patterned metal layers, positioned on top of each other and mutually connected by via or contact plugs. The seal ring structure 30 is common in the art and is utilized to protect the active integrated circuit 18 from being damaged by cracks originating from the wafer dicing process. The seal ring structure 30 may be single seal barrier wall or dual-wall barriers formed in layers of similar or dissimilar dielectric materials 42.

As shown in FIG. 2, the seal structures are manufactured step by step as sequential depositions of insulators and metals in conjunction together with the fabrication of the integrated circuit elements. First, a heavily doped region (not shown) is diffused into the semiconductor material 40 such as a silicon substrate in a process needed otherwise for fabricating strongly doped surface regions in some circuit elements. This heavily doped region serves as an anchor for the seal ring structure to be built, and permits the application of specific electrical potentials to the seal ring structure, such as ground potential or Vss. Finally, a protective overcoat 44 such as silicon nitride covering both the circuit chips and the dicing streets is deposited over the whole wafer.

As aforementioned, the fabrication of the seal ring structure is known in the art, and details of this will be skipped over in the following text.

It has been found that the conventional seal ring structure 30 at the weak corners 13 where mechanical stress concentrated thereon during wafer dicing is not adequate to stop the aforementioned interface de-lamination propagation. To overcome the overwhelming interface de-lamination produced during wafer dicing at the vulnerable corners 13, in accordance with the preferred embodiment of this invention, a reinforcing structure 20 is provided, which is merely disposed around the corners 13 of each circuit chip 12. The reinforcing structure 20 comprises a first trench 22 formed by etching through the overcoat 44 into the inter-layer dielectric 42 with a suitable mask and is disposed merely around the four corners 13 of each circuit chip 12. A reinforcing second trench 24 disposed in proximity to the first trench for preventing interface de-lamination of the inter-layer dielectric 42 at the four corners 13 during or after the mechanical wafer dicing. The reinforcing second trench 24 is likewise etched through the overcoat 24 into the inter-layer dielectric 42.

According to this preferred embodiment, the first and second trenches are formed by etching through the overcoat 44, the inter-layer dielectric 42, then reaching to the silicon substrate 40. However, it is to be understood that the recessed depth of the first and second trenches into the inter-layer dielectric 42 should not limit this invention. In another case, only one of the first and second trenches reaches to the silicon substrate 40 is applicable.

Briefly referring back to FIG. 1, the first and second trenches are deliberately configured such that most of the interface de-lamination defects are eliminated by the reinforcing second trench 24, while the rest of them are completely screened out by the first trench 22. However, some other variations may be applied to achieve the goal of this invention.

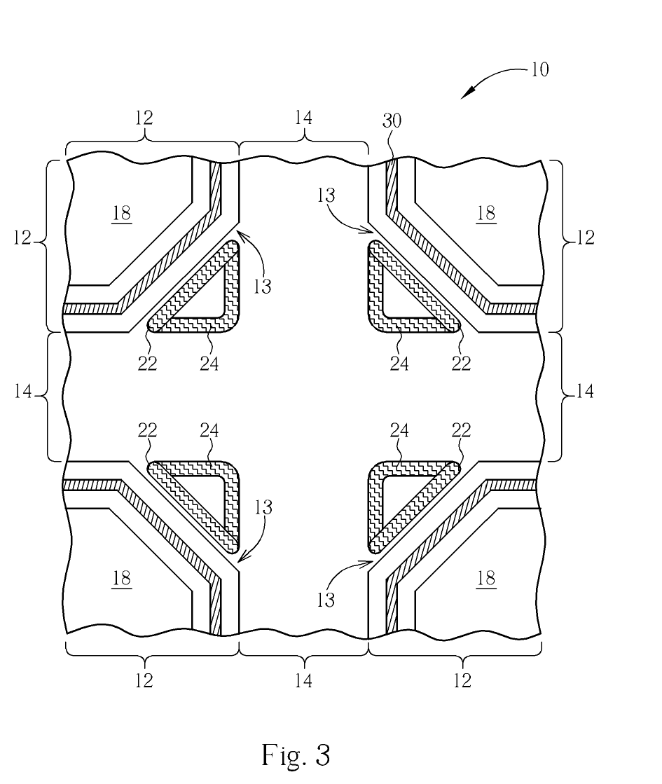

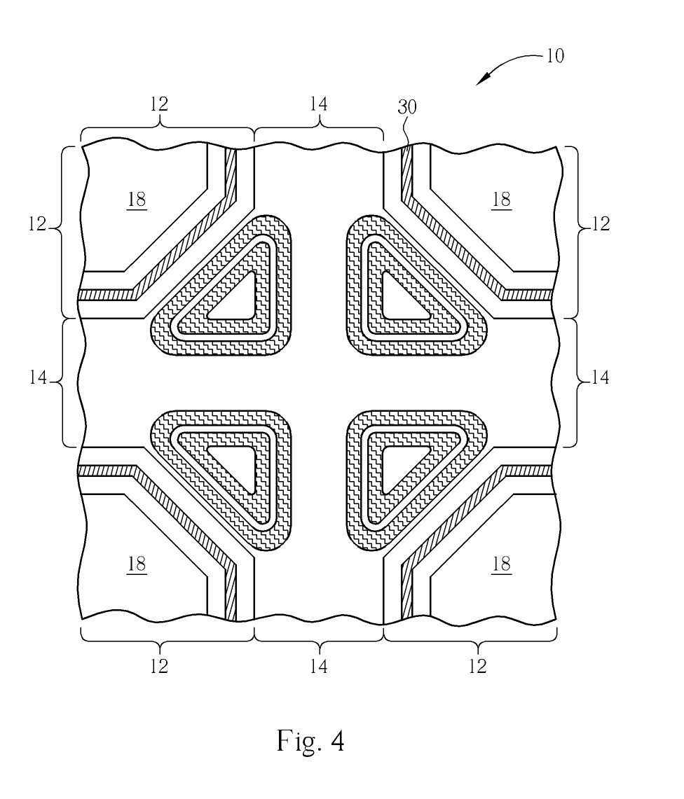

Referring to FIG. 3, in accordance with another preferred embodiment, the first trench 22 intersects the second trench 24 to form a triangular reinforcing structure. The first trench 22 and the second trench 24 are both formed by etching through the overcoat 44 into the inter-layer dielectric 42. Referring to FIG. 4, in accordance with still another preferred embodiment, two triangular trench structures are used, wherein one triangular trench structure encompasses the other.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor wafer comprising:
a plurality of active circuit die areas, each of which being bordered by a dicing line region through which the plurality of active circuit die areas are separated from each other by mechanical wafer dicing, wherein each of the plurality of active circuit die areas has substantially four corners;
an overcoat covering both the active circuit die areas and the dicing line region;
an inter-layer dielectric layer disposed underneath the overcoat;
a first trench formed within the dicing line region, wherein the first trench is formed by etching through the overcoat into the inter-layer dielectric layer and is disposed merely around the four corners of each active circuit die area;
a reinforcing second trench etched through the overcoat into the inter-layer dielectric layer, wherein the second trench is disposed in proximity to the first trench for preventing interface de-lamination of the inter-layer dielectric layer at the four corners during or after the mechanical wafer dicing; and
a die seal ring in between the active circuit chip area and the first trench.

2. The semiconductor wafer according to claim 1 wherein the semiconductor wafer further comprises a silicon substrate, and wherein at least one of the first and second trenches is formed by etching through the overcoat and the inter-layer dielectric layer, whereby reaching to the silicon substrate.

3. The semiconductor wafer according to claim 1 wherein the overcoat includes silicon nitride.

4. The semiconductor wafer according to claim 1 wherein the four corners are not right-angled.

5. The semiconductor wafer according to claim 1 wherein the first trench intersects the reinforcing second trench.

6. The semiconductor wafer according to claim 5 wherein the first trench intersects the reinforcing second trench to form a triangular trench.

7. The semiconductor wafer according to claim 1 wherein the first trench and the reinforcing second trench are both triangular trenches, and wherein the reinforcing second trench encompasses the first trench.

8. A semiconductor wafer comprising:
a plurality of active circuit die areas, each of which being bordered by a dicing line region through which the plurality of active circuit die areas are separated from each other, wherein each of the plurality of active circuit die areas has substantially four corners;
an overcoat covering both the active circuit die areas and the dicing line region;
a first trench formed by etching through the overcoat and disposed merely around the four corners of each active circuit die area that are vulnerable to interface de-lamination propagation;
a reinforcing second trench etched through the overcoat and disposed in proximity to the first trench; and
a die seal ring in between the active circuit chip area and the first trench.

9. The semiconductor wafer according to claim 8 wherein the semiconductor wafer further comprises an inter-layer dielectric layer under the overcoat and a silicon substrate, and wherein at least one of the first and second trenches is formed by etching through the overcoat and the inter-layer dielectric layer, whereby reaching to the silicon substrate.

10. The semiconductor wafer according to claim 8 wherein the overcoat includes silicon nitride.

11. The semiconductor wafer according to claim 8 wherein the four corners are not right-angled.

12. The semiconductor wafer according to claim 8 wherein the first trench intersects the reinforcing second trench.

13. The semiconductor wafer according to claim 12 wherein the first trench intersects the reinforcing second trench to form a triangular trench.

14. The semiconductor wafer according to claim 8 wherein the first trench and the reinforcing second trench are both triangular trenches, and wherein the reinforcing second trench encompasses the first trench.
